(19) United States
(12) Patent Application Publication
(10) Pub. No.: US 2018/0246141 A1
(43) Pub. Date: Aug. 30, 2018

(54) DYNAMIC QUANTITY SENSOR

(71) Applicant: DENSO CORPORATION, Kariya-city, Aichi-pref. (JP)

(72) Inventor: Eiichi TAKETANI, Kariya-city (JP)

(21) Appl. No.: 15/758,545

(22) PCT Filed: Oct. 20, 2016
(86) PCT No.: PCT/JP2016/081096

§ 371 Date: Mar. 8, 2018

(30) Foreign Application Priority Data
Nov. 3, 2015 (JP) 2015-216228

(51) Int. Cl. G01P 15/125; G01P 15/18; H01L 29/84

(52) U.S. Cl. CPC G01P 15/125; G01P 2015/0822; H01L 29/84; G01P 15/18

(57) ABSTRACT

A dynamic quantity sensor includes: a support portion with a fixed electrode; a plate-shaped fixing portion fixed to the support portion; a beam portion supported by the fixing portion and extending in one direction; a first weight on one side of the fixing portion in an other direction, coupled to the beam portion, and providing a space between a connecting portion and a tip portion by coupling the connecting portion connecting to the beam portion and the tip portion opposite to the beam portion through a coupling portion extending in the other direction; and a second weight portion opposite to the first weight portion and coupled to the beam portion. The first weight portion has a length larger than the second weight portion. A dynamic quantity is detected based on a change in a capacitance between the fixed electrode and each of the first and second weight portions.

### CROSS REFERENCE TO RELATED APPLICATIONS

This application is a U.S. national stage application of International Application No. PCT/JP2016/081096 filed on Oct. 20, 2016 and is based on Japanese Patent Application No. 2015-216228 filed on Nov. 3, 2015, the disclosures of which are incorporated herein by reference.

### TECHNICAL FIELD

The present disclosure relates to a dynamic quantity sensor having a lever structure.

### BACKGROUND

Up to now, an acceleration sensor as disclosed in Patent Literature 1 has been proposed. The acceleration sensor is a capacitance type acceleration sensor in which a fixed electrode and a movable electrode are disposed so as to face each other and utilizes a displacement of the movable electrode due to an inertial force and a change in a capacitance between the electrodes due to the displacement to detect an acceleration.

In addition, in a triaxial acceleration sensor having detection units in respective X-, Y-, and Z-directions such as the acceleration sensor disclosed in Patent Literature 1, in the detection unit in the Z-direction, the movable electrode is of a lever structure centered on a fulcrum, which is different from the detection units in the X- and Y-directions in which the movable electrode is supported by a spring. The two fixed electrodes are disposed to face the movable electrode in the Z-direction, and when the movable electrode receives the inertial force, a difference occurs in a capacitance between the respective fixed electrodes and the movable electrode. The triaxial acceleration sensor detects the acceleration in the Z-direction with the use of the difference in capacitance.

### PATENT LITERATURE

Patent Literature 1: JP-2012-37341-A

### SUMMARY

In order to raise a sensitivity in the Z-direction and to detect even a small acceleration in the triaxial acceleration sensor, there is a need to increase a difference in mass between two weights aligned in the Y-direction of a lever configuring the movable electrode. For example, in the detection units in the X-and Y-directions, the mass of the weights can be increased by increasing a thickness in the Z-direction. However, in the detection unit in the Z-direction, even if a thickness of the movable electrode is increased, a balance between the right and the left of the lever does not change and a torsion beam becomes hard. Therefore, an increase in the thickness in the Z-direction does not contribute to an increase in the sensitivity.

Therefore, in order to increase the sensitivity in the Z-direction when using a uniform material, there is a need to set one of the two weights aligned in the Y-direction of the lever, which is longer in a distance from the fulcrum to the tip, to be further longer, to increase a torque.

However, if the movable electrode is lengthened in the detection unit in the Z-direction, a chip size of the entire acceleration sensor combined with the detection units in the X and Y-directions increases.

It is an object of the present disclosure to provide a dynamic quantity sensor that improves a detection sensitivity while reducing an increase in a chip size.

According to an aspect of the present disclosure, a dynamic quantity sensor includes: a support portion on which a fixed electrode is arranged; a plate-shaped fixing portion that is fixed to the support portion; a beam portion that is supported by the fixing portion and extends in one direction on a plane of the fixing portion; a first weight that is disposed on one side of the fixing portion in an other direction perpendicular to the one direction on the plane of the fixing portion, is coupled to the beam portion, and provides a space between a connecting portion and a tip portion by coupling the connecting portion connecting to the beam portion and the tip portion disposed on a side opposite to the beam portion through a coupling portion extending in the other direction; and a second weight portion that is disposed on a side of the fixing portion opposite to the first weight portion in the other direction, and is coupled to the beam portion. The first weight portion has a length in the other direction larger than that of the second weight portion. A dynamic quantity is detected based on a change in a capacitance between the fixed electrode and each of the first weight portion and the second weight portion when the first weight portion and the second weight portion are displaced.

According to the above configuration, the length of the first weight portion in the other direction is larger than the length of the second weight portion, and the space is provided between the connecting portion to the beam portion and the tip portion of the first weight portion. Therefore, the detection sensitivity can be improved while reducing an increase in the chip size, by leveraging the space for placement of the devices or the like.

### BRIEF DESCRIPTION OF DRAWINGS

The above and other objects, features and advantages of the present disclosure will become more apparent from the following detailed description made with reference to the accompanying drawings. In the drawings:

FIG. 1 is a cross-sectional view of a dynamic quantity sensor according to a first embodiment.

FIG. 2 is a cross-sectional view of the dynamic quantity sensor according to the first embodiment.

FIG. 3 is a plan view of an XY sensor.

FIG. 4 is a perspective view of the XY sensor.

FIGS. 5A to 5E are cross-sectional views showing a method of manufacturing an MEMS (micro electro mechanical systems) wafer.

FIGS. 6A to 6D are cross-sectional views showing a method of manufacturing a CAP wafer.

FIGS. 7A to 7E are cross-sectional views showing a method of manufacturing the dynamic quantity sensor.

FIG. 8 is a cross-sectional view showing the operation of the dynamic quantity sensor.

FIG. 9 is a cross-sectional view of a conventional dynamic quantity sensor.

FIG. 10 is a cross-sectional view of a conventional dynamic quantity sensor.

FIG. 11 is a cross-sectional view of a modification of the first embodiment.

FIG. 12 is a cross-sectional view of a dynamic quantity sensor according to a second embodiment.

FIGS. 13A to 13C are cross-sectional views showing a method of manufacturing a CAP wafer.

FIGS. 14A to 14E are cross-sectional views showing a method of manufacturing the dynamic quantity sensor.

FIG. 15 is a cross-sectional view of a dynamic quantity sensor according to a third embodiment.

FIGS. 16A to 16D are cross-sectional views showing a method of manufacturing an MEMS wafer.

FIGS. 17A to 17D are cross-sectional views showing the method of manufacturing the MEMS wafer.

FIGS. 18A and 18B are cross-sectional views showing a method of manufacturing a CAP wafer.

FIGS. 19A to 19C are cross-sectional views showing a method of manufacturing the dynamic quantity sensor.

FIG. 20 is a cross-sectional view of a dynamic quantity sensor according to a fourth embodiment.

FIG. 21 is a cross-sectional view of the dynamic quantity sensor according to the fourth embodiment.

FIG. 22 is a cross-sectional view of the dynamic quantity sensor according to the fourth embodiment.

FIG. 23 is a cross-sectional view of a dynamic quantity sensor according to a fifth embodiment.

FIG. 24 is a perspective view of a dynamic quantity sensor according to a sixth embodiment.

FIG. 25 is a cross-sectional view of a dynamic quantity sensor according to a seventh embodiment.

FIG. 26 is a cross-sectional view taken along a line XXVI-XXVI in FIG. 25.

FIG. 27 is a perspective view of a dynamic quantity sensor according to another embodiment.

FIG. 28 is a cross-sectional view of a dynamic quantity sensor according to another embodiment.

### EMBODIMENTS

Embodiments of the present disclosure will be described below with reference to the accompanying drawings. In the following respective embodiments, parts identical with or equivalent to each other are denoted by the same symbols for description.

### First Embodiment

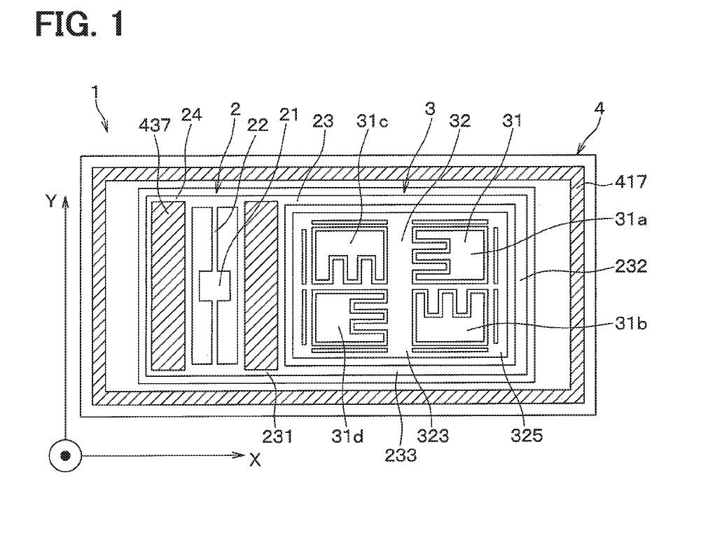

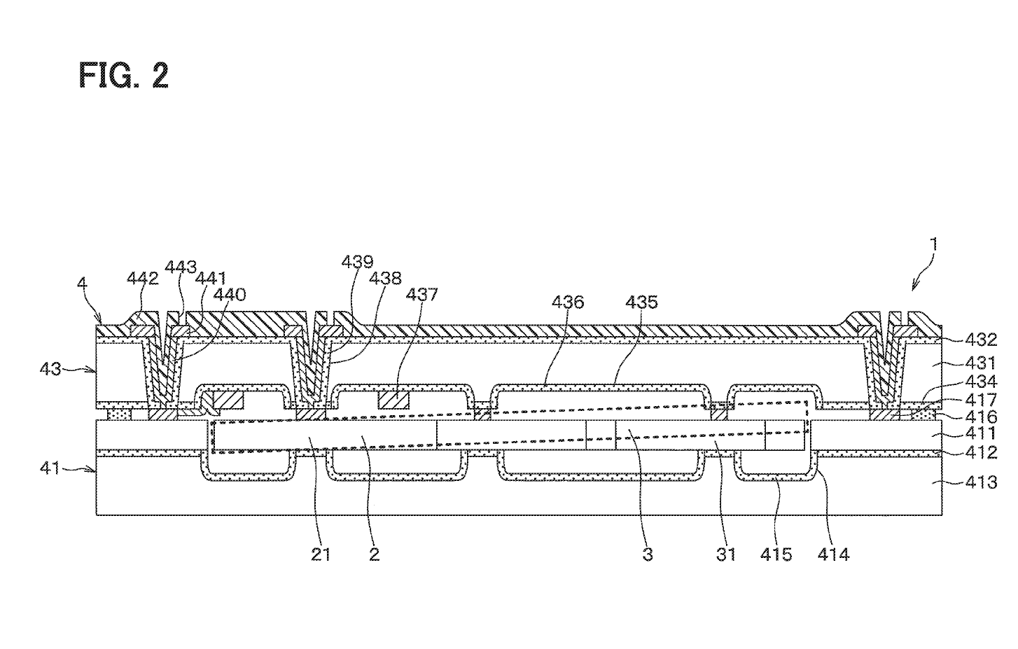

A first embodiment will be described. A dynamic quantity sensor 1 according to the present embodiment is a sensor that detects accelerations in X, Y, and Z-directions perpendicular to each other, and as shown in FIGS. 1 and 2, includes a Z sensor 2, an XY sensor 3, and a support portion 4. As shown in FIG. 2, the dynamic quantity sensor 1 is configured such that the Z sensor 2 and the XY sensor 3 are sealed in the support portion 4, and a part of the Z sensor 2 and a part of the XY sensor 3 are fixed to the support portion 4.

The Z sensor 2 is a sensor that detects the acceleration in the Z-direction, and includes a fixing portion 21, a beam portion 22, a weight portion 23, and a weight portion 24. In the present embodiment, the fixing portion 21, the beam portion 22, and the weight portions 23, 24 are formed by processing an active layer 411 which will be described later. Further, the respective weight portions 23 and 24 are disposed on both sides of the fixing portion 21 and the fixing portion 21 is coupled to the weight portions 23 and 24 through the beam portion 22, to thereby configure a lever structure having the fixing portion 21 as a fulcrum.

The fixing portion 21 is a portion for fixing the Z sensor 2 to the support portion 4 and is formed in a plate-shape. As shown in FIG. 1, a surface of the fixing portion 21 parallel to an XY-plane is quadrangular. As shown in FIG. 2, a back surface of the fixing portion 21 is fixed to a sacrificial layer 412 which will be described later, and the surface of the fixing portion 21 is fixed to a CAP wafer 43 which will be described later.

The beam portion 22 is supported by the fixing portion 21 and extends toward both sides in a direction parallel to the surface of the fixing portion 21, centered on the fixing portion 21, in this case, in the Y-direction. On a back surface of the beam portion 22, the sacrificial layer 412 to be described later is removed, and the beam portion 22 is disposed in a state separated from the support layer 413 and the CAP wafer 43 to be described later. The weight portions 23 and 24 are displaced in the Z-direction due to twisting of the beam portion 22.

The weight portion 23 is disposed on one side of the fixing portion 21 in the X-direction and is coupled to the beam portion 22. As shown in FIG. 1, a connecting portion 231 of the weight portion 23 to the beam portion 22 and a tip portion 232 of the weight portion 23 opposite to the beam portion 22 are coupled to each other by a coupling portion 233 extending in the X-direction, to thereby provide a space between the connecting portion 231 to the beam portion 22 and the tip portion 232.

The weight portion 24 is disposed on a side of the fixing portion 21 opposite to the weight portion 23 in the X-direction and is coupled to the beam portion 22. The weight portion 23 and the weight portion 24 correspond to a first weight portion and a second weight portion, respectively.

The connecting portion 231 and the weight portion 24 each have a U-shaped upper surface, are disposed to face each other on both sides of the fixing portion 21, and are coupled to the beam portion 22 at both end portions of those portion. The weight portion 23 has a length in the X-direction larger than the weight portion 24 and a mass larger than the weight portion 24.

At least a part of the XY sensor 3 corresponding to the device is disposed in the space provided between the connecting portion 231 and the tip portion 232. In the present embodiment, as shown in FIG. 1, the coupling portion 233 includes two straight beams, and the XY sensor 3 is placed in a space surrounded by the connecting portion 231, the coupling portion 233, and the tip portion 232.

The XY sensor 3 is a sensor that detects accelerations in the X-direction and the Y-direction, and includes a fixing portion 31 and a movable portion 32. In the present embodiment, the fixing portion 31 and the movable portion 32 as well as the fixing portion 21, the beam portion 22, and the weight portions 23 and 24 of the Z sensor 2 are formed by processing the active layer 411 which will be described later.

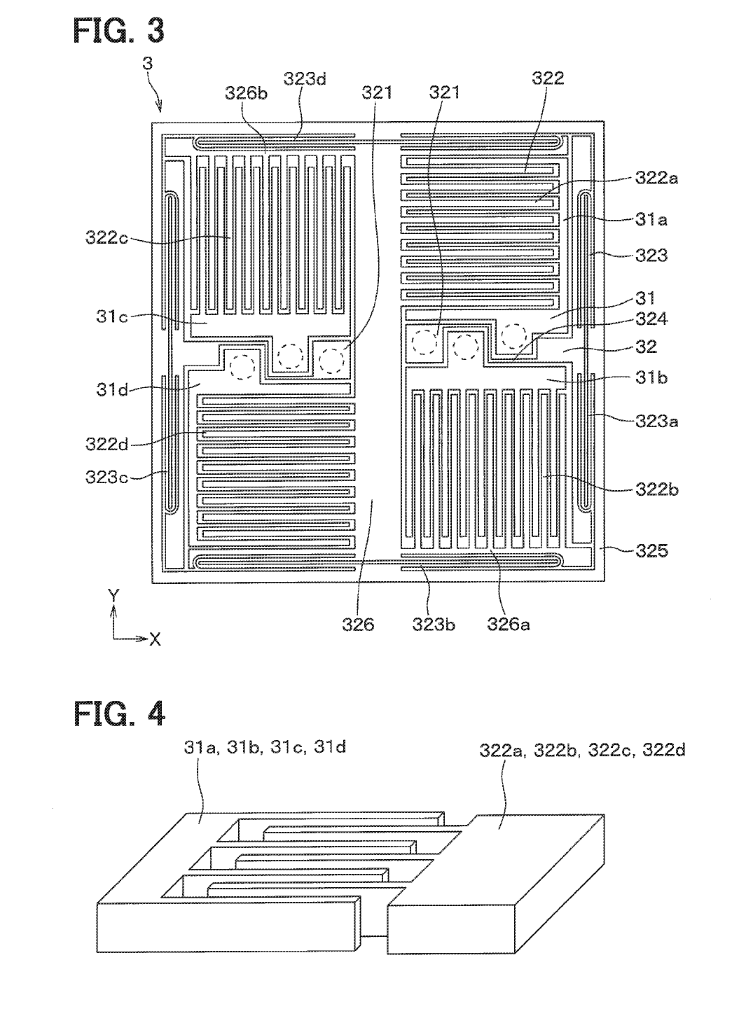

As shown in FIGS. 1 and 3, the fixing portion 31 includes four comb teeth-shaped electrodes 31a, 31b, 31c, and 31d. The electrodes 31a, 31b, 31c, and 31d correspond to a first electrode.

As shown in FIG. 2, a surface of the fixing portion 31 is fixed to the CAP wafer 43 so that an electrical connection can be performed between the fixing portion 31 and an external wire as necessary. Further, a back surface of the fixing portion 31 is fixed to the sacrificial layer 412. Although the electrodes 31a, 31b, 31c, and 31d are not shown in FIG. 2, those four electrodes are fixed to the support portion 4. The fixing portion 31 and fixing portions 321 to be described later are fixed to the sacrificial layer 412 and the CAP wafer 43 in regions indicated by broken lines in FIG. 3.

The electrodes 31a and 31b are disposed on one side in the X-direction with respect to a center of the XY sensor 3 and the electrodes 31c and 31d are disposed on the other side. Further, the electrodes 31a and 31c are disposed on one side in the Y-direction with respect to the center of the XY sensor 3, and the electrodes 31b and 31d are disposed on the other side.

The electrodes 31a and 31d are electrodes for detecting the acceleration in the Y-direction. As shown in FIG. 3, the comb teeth of the electrodes 31a and 31d are parallel to the X-direction and are directed toward an inside of the XY sensor 3. The electrodes 31b and 31c are electrodes for detecting the acceleration in the X-direction, and the comb teeth of the electrodes 31b and 31c are parallel to the Y-direction and are directed to an outside of the XY sensor 3.

In the present embodiment, in order to reduce an influence of a stress generated inside and outside the XY sensor 3, as shown in FIG. 3, the electrode 31a and the electrode 31d are disposed diagonally, and the electrode 31b and the electrode 31c are disposed diagonally. However, the electrodes 31a, 31b, 31c, and 31d may be disposed at other positions.

As shown in FIG. 3, the movable portion 32 includes the two fixing portions 321, four electrodes 322, four spring portions 323, a beam portion 324, a frame body 325, and a coupling portion 326.

As shown in FIG. 1 and FIG. 3, an upper surface of the frame body 325 is formed in a quadrangular shape including sides parallel to the X-direction and sides parallel to the Y-direction. The spring portions 323 are disposed inside the respective four sides of the frame body 325, and the fixing portion 31, the fixing portion 321, the electrodes 322, the beam portion 324, and the coupling portion 326 are disposed on the inside of the frame 325 and the spring portions 323.

Each of the four spring portions 323 is formed of a leaf spring. The four spring portions 323 disposed on a right side, a lower side, a left side, and an upper side of a paper surface of FIG. 3 are referred to as spring portions 323a, 323b, 323c, and 323d, respectively.

As shown in FIG. 3, the spring portion 323b and the spring portion 323d are coupled to each other by the coupling portion 326 extending in the Y-direction. The fixing portions 321 are disposed on both sides of a central portion of the coupling portion 326 in a state separated from the coupling portion 326. The fixing portions 321 are configured to support the movable portion 32, front surfaces of the fixing portions 321 are fixed to the CAP wafer 43, and back surfaces of the fixing portions 321 are fixed to the sacrificial layer 412.

As shown in FIG. 3, the two fixing portions 321 are coupled to the respective spring portions 323a and 323c through the beam portion 324 extending in the X-direction. The beam portion 324 extends between the electrode 31a and the electrode 31b and between the electrode 31c and the electrode 31d.

In the present embodiment, the beam portion 324 is meandering as shown in FIG. 3 in order to reduce a size of the XY sensor 3, but the beam portion 324 may have another shape.

As shown in FIG. 3, four comb teeth-shaped electrodes 322 are coupled to the coupling portion 326. The four electrodes 322 are referred to as respective electrodes 322a, 322b, 322c, and 322d. The electrodes 322a, 322b, 322c, and 322d correspond to a second electrode.

The electrode 322a and the electrode 322d are extended on both sides of the coupling portion 326 so that the comb teeth are parallel to the X-direction. As shown in FIGS. 3 and 4, the electrodes 322a and 322d face the electrodes 31a and 31d, respectively. An extension portion 326a extends from one end of the coupling portion 326 in the Y-direction toward one way in the X-direction and an extension portion 326b extends from the other end in the other way in the X-direction. The electrode 322b and the electrode 322c are extended from the extension portions 326a and 326b so that the comb teeth are parallel to the Y-direction, and face the electrodes 31b and 31c, respectively.

The support portion 4 supports the Z sensor 2 and the XY sensor 3, and as shown in FIG. 2, includes an MEMS wafer 41 and the CAP wafer 43. The MEMS wafer 41 is an SOI (silicon on insulator) wafer formed by sequentially stacking the active layer 411, the sacrificial layer 412, and the support layer 413. The Z sensor 2 and the XY sensor 3 are formed by patterning the active layer 411. A portion of the active layer 411 located outside the Z sensor 2 and the XY sensor 3 configures a part of the support portion 4. The active layer 411 and the support layer 413 are made of, for example, Si or the like, and the sacrificial layer 412 is made of, for example, SiO2 or the like.

In a portion where the Z sensor 2 and the XY sensor 3 are formed, the sacrificial layer 412 is removed and a part of the support layer 413 is removed to provide a recess portion 414. However, the sacrificial layer 412 and the support layer 413 are left unremoved in lower portions of the fixing portion 21 of the Z sensor 2 and the fixing portions 31 and 321 of the XY sensor 3. An oxide film 415 is formed on a surface of the recess portion 414.

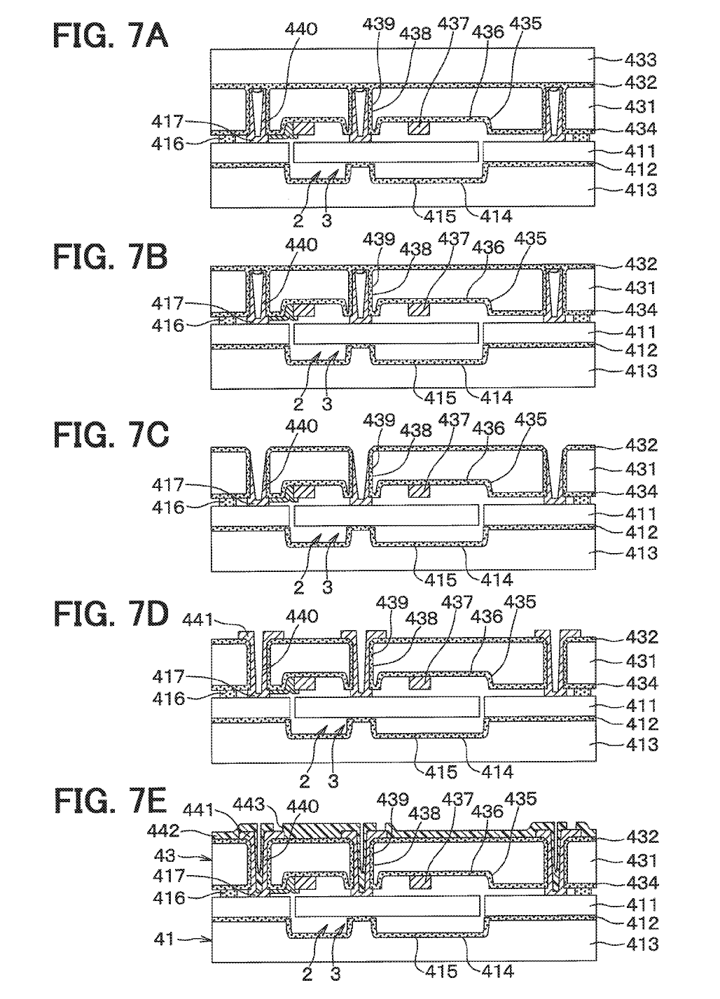

A spacer 416 is formed on an outer peripheral portion of an upper surface of the active layer 411. The spacer 416 is configured to adjust a position of the CAP wafer 43 when metal bonding is performed in a step shown in FIG. 7A to be described later, and is made of 902 in this example.

In addition, a metal layer 417 is formed on an upper surface of the active layer 411. The metal layer 417 serves as a bonding agent and an electrode material for metal bonding performed in the step shown in FIG. 7A, and is made of Al in this example. The metal layer 417 may be made of Au, Cu, or the like. Also, the metal layer 417 may be made of different metals joined together by a joining method in which a solid phase and a liquid phase intervene between the metals such as a eutectic reaction, instead of the same type of metal.

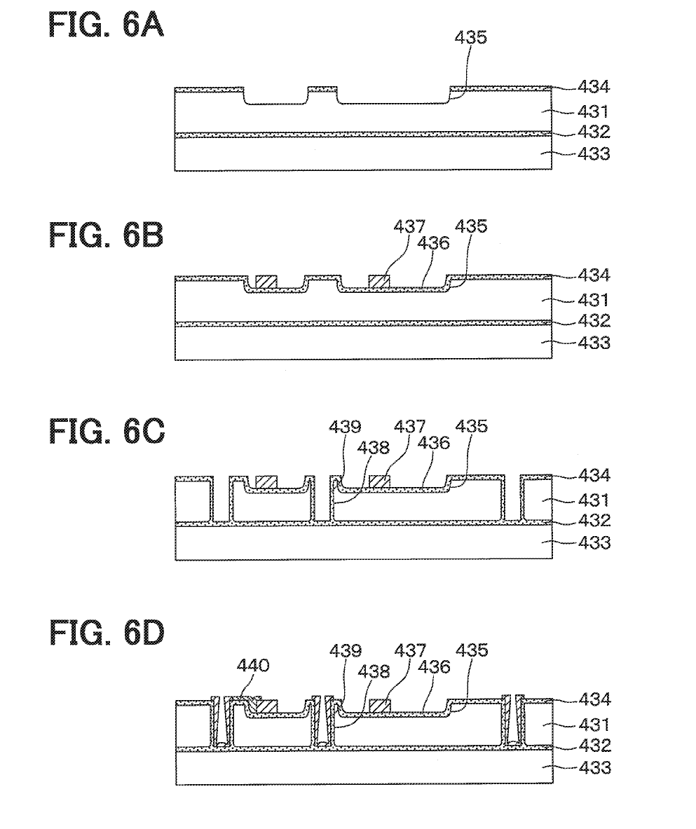

The CAP wafer 43 is formed by processing an SOI wafer formed by sequentially stacking an active layer 431, a sacrificial layer 432, and a support layer 433 (refer to FIGS. 6A-6D). In a manufacturing process of the CAP wafer 43, the support layer 433 is removed, and as shown in FIG. 2, a wire 441 and a passivation film 442 are formed on a surface of the sacrificial layer 432.

An insulating layer 434 is formed on a surface of the active layer 431. In portions corresponding to the Z sensor 2 and the XY sensor 3, the insulating layer 434 is removed, a part of the active layer 431 is removed to form a recess portion 435.

An oxide film 436 for potential separation is formed on a surface of the recess portion 435. A fixed electrode 437 is formed on a portion of a surface of the oxide film 436 which faces the connecting portion 231 and the weight portion 24. In this example, the fixed electrode 437 is made of Poly-Si.

Vias 438 that are TSV (through-silicon via) that penetrate through the insulating layer 434, the active layer 431, and the sacrificial layer 432 are provided in the CAP wafer 43. A side wall oxide film 439 is formed on a surface of each via 438.

A wire 440 is formed on a portion of a surface of the side wall oxide film 439 and a surface of the insulating layer 434, which connects the sidewall oxide film 439 and the fixed electrode 437. The wire 440 is connected to the metal layer 417 of the MEMS wafer 41 on the insulating layer 434 side. A wire 441 is formed on a surface of the sacrificial layer 432 so as to be connected to the wire 440.

A passivation film 442 is formed on surfaces of the sacrificial layer 432 and the wires 440, 441. The passivation film 442 is configured to provide the dynamic quantity sensor 1 with a moisture resistance, and in this case, the passivation film 442 is made of SiN. The passivation film 442 may be made of polyimide resin such as PIQ (registered trademark).

opening portions 443 are provided in portions of the passivation film 442 which are formed on an upper surface of the wire 441. As a result, the fixed electrode 437, the weight portions 23, 24 and the like can be connected to an external wire through the wires 440 and 441.

As will be described later, when the acceleration is applied to the dynamic quantity sensor 1, capacitances between the weight portion 23 and the fixed electrode 437, between the weight portion 24 and the fixed electrode 437, and between the fixing portion 31 and the movable portion 32 change. In the present embodiment, the dynamic quantity sensor 1 and a control device not shown are connected to each other so as to differentially amplify changes in those capacitances generated at the time of the acceleration application. For example, when a power supply voltage is 5 V, potentials of the weight portions 23 and 24 and the movable portion 32 are set to 5 V. The fixing portion 31 and the fixed electrode 437 are connected to an input terminal of the control device not shown through the metal layer 417 and the wires 440, 441.

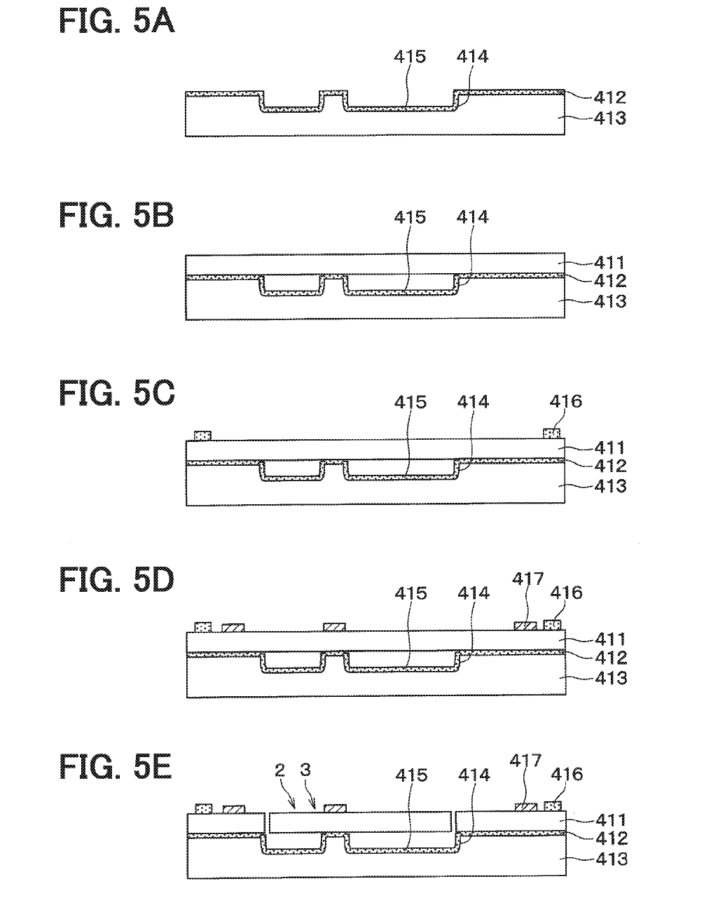

A method of manufacturing the dynamic quantity sensor 1 will be described. In the present embodiment, the dynamic quantity sensor 1 is manufactured by a method using the metal bonding. The dynamic quantity sensor 1 is manufactured as follows. The MEMS wafer 41 is manufactured in a process shown in FIGS. 5A to 5E, the CAP wafer 43 is manufactured in a process shown in FIGS. 6A to 6D, and thereafter the MEMS wafer 41 and the CAP wafer 43 are joined to each other in a process shown in FIGS. 7A to 7E, and wire formation and the like are performed.

A method of manufacturing the MEMS wafer 41 will be described with reference to FIGS. 5A to 5E. First, a substrate in which the sacrificial layer 412 is stacked on an upper surface of the support layer 413 is prepared. Then, as shown in FIG. 5A, the sacrificial layer 412 is removed by etching in portions corresponding to the Z sensor 2 and the XY sensor 3, and a part of the support layer 413 is removed by etching with the sacrificial layer 412 as a mask, thereby forming the recess portion 414. However, in the portions corresponding to the fixing portions 21, 31, and 321, the sacrificial layer 412 and the support layer 413 are left without being removed. Further, in a step shown in FIG. 5A, after the recess portion 414 has been provided, the oxide film 415 is formed on a surface of the recess portion 414.

After the step shown in FIG. 5A, as shown in FIG. 5B, a cavity SOI process is performed to join the active layer 411 as the MEMS layer to the surface of the sacrificial layer 412 by direct joining.

In a step shown in FIG. 5C, the spacer 416 are formed on the surface of the active layer 411 by photolithography and etching. In a step shown in FIG. 5D, the metal layer 417 is formed on the surface of the active layer 411 by photolithography and etching. In a step shown in FIG. 5E, the active layer 411 is processed by etching to form the Z sensor 2 and the XY sensor 3.

A method of manufacturing the CAP wafer 43 will be described with reference to FIGS. 6A to 6D. First, an SOI wafer is prepared by laminating the active layer 431, the sacrificial layer 432, and the support layer 433 in the stated order, and the insulating layer 434 is formed on the surface of the active layer 431. As shown in FIG. 6A, the insulating layer 434 is removed in the portions corresponding to the Z sensor 2 and the XY sensor 3 by etching and a part of the active layer 431 is removed by etching with the use of the insulating layer 434 as a mask, to thereby form the recess portion 435. However, in the portions corresponding to the fixing portions 21, 31, and 321, the insulating layer 434 and the active layer 431 are left without being removed.

In a step shown in FIG. 6B, the surface of the recess portion 435 is thermally oxidized to form the oxide film 436, and the fixed electrode 437 is formed on the surface of the oxide film 436 by photolithography and etching. In a step shown in FIG. 6C, the insulating layer 434 and the active layer 431 are removed by etching to form the vias 438. Then, the surface of each via 438 is thermally oxidized to form the side wall oxide film 439. In a step shown in FIG. 6D, the wire 440 is formed by photolithography and etching in the portions of the surface of the side wall oxide film 439 and the surface of the insulating layer 434, which couple the side wall oxide film 439 and the fixed electrode 437 together.

The bonding of the MEMS wafer 41 and the CAP wafer 43 thus manufactured and the steps after the bonding will be described with reference to FIGS. 7A to 7E. In a step shown in FIG. 7A, the MEMS wafer 41 and the CAP wafer 43 are bonded together by metal bonding such as thermocompression bonding or diffusion bonding.

As a result, the spacer 416 formed on the MEMS wafer 41 and the insulating layer 434 formed on the CAP wafer 43 come into contact with each other. Further, the metal layer 417 formed on the MEMS wafer 41 and the wire 440 formed on the CAP wafer 43 are bonded to each other. Then, the Z sensor 2 and the XY sensor 3 formed by processing the active layer 411 of the MEMS wafer 41 are sealed with the CAP wafer 43.

In a step shown in FIG. 7B, the support layer 433 is removed by grinding and polishing, and etching to expose the sacrificial layer 432. In a step shown in FIG. 7C, a portion of the sacrificial layer 432 which is a bottom portion of the via 438 is removed by etching to open the via 438.

In a step shown in FIG. 7D, the wire 441 is formed in the vicinity of the via 438 on the surface of the sacrificial layer 432 by photolithography and etching, and the wire 441 and the wire 440 are connected to each other. In a step shown in FIG. 7E, the passivation film 442 is formed on the surfaces of the sacrificial layer 432 and the wires 440 and 441 by a CVD (chemical vapor deposition) method, a coating method, or the like. Further, the opening portions 443 are pierced in the passivation film 442 by etching to expose a part of the wire 441.

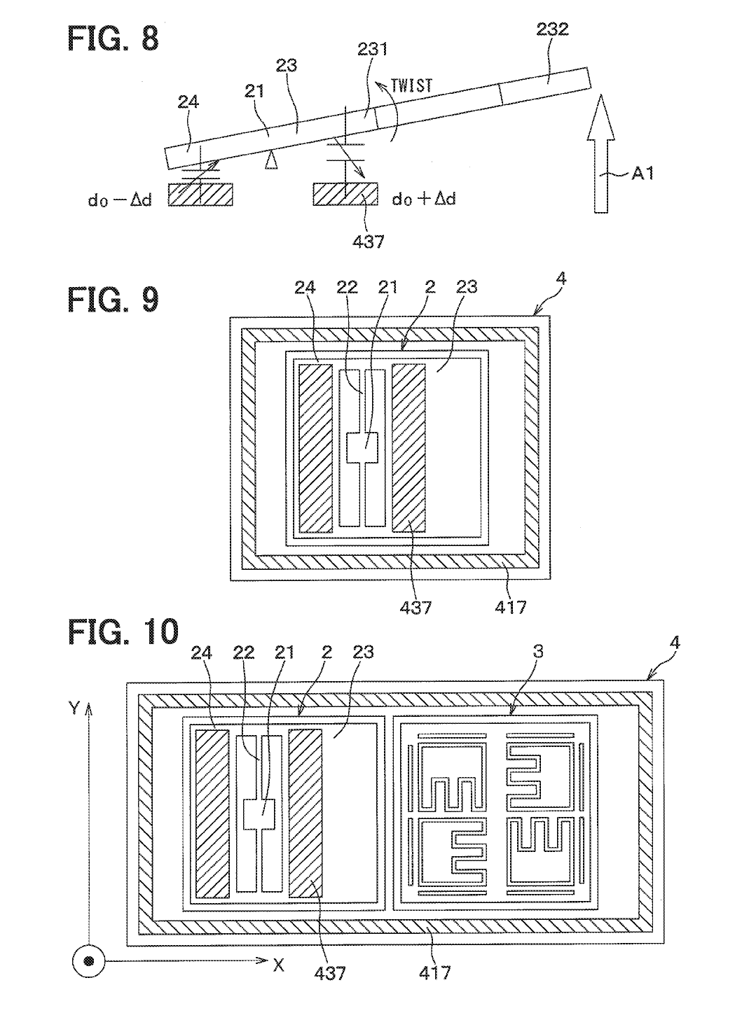

The operation of the dynamic quantity sensor 1 will be described. When the dynamic quantity sensor 1 is accelerated in the Z-direction, the weight portions 23 and 24 are displaced as indicated by a broken line in FIG. 2 and an arrow Al in FIG. 8. Then, as shown in FIG. 8, distances between the fixed electrode 437 of the CAP wafer 43 and each of the weight portion 23 and the weight portion 24 change to change capacitances. The Z sensor 2 obtains a change in the capacitances between the fixed electrode 437 of the CAP wafer 43 and each of the weight portion 23 and the weight portion 24 when the weight portions 23 and 24 are displaced according to a change in the potential of the fixed electrode 437, and detects the acceleration in the Z-direction with the use of the obtained change in the capacitance.

When the dynamic quantity sensor 1 is accelerated in the X-direction, the electrode 322b that faces the electrode 31b is displaced to change an capacitance between the electrode 31b and the electrode 322b. In addition, the electrode 322c that faces the electrode 31c is displaced to change a capacitance between the electrode 31c and the electrode 322c. The XY sensor 3 obtains the change in those capacitances according to the potentials of the electrodes 31b and 31c, and detects the acceleration in the X-direction with the use of the obtained change in the capacitance.

Likewise, when the dynamic quantity sensor 1 is accelerated in the Y-direction, the electrode 322a that faces the electrode 31a is displaced to change an capacitance between the electrode 31a and the electrode 322a. In addition, the electrode 322d that faces the electrode 31d is displaced to change a capacitance between the electrode 31d and the electrode 322d. The XY sensor 3 obtains the change in those capacitances according to the potentials of the electrodes 31a and 31d, and detects the acceleration in the Y-direction with the use of the obtained change in the capacitance.

Since the fixing portion 31 and the movable portion 32 of the XY sensor 3 are disposed in the space between the connecting portion 231 and the tip portion 232 in a state separated from the weight portion 23, the Z sensor 2 and the XY sensor 3 operate without interfering with each other.

In order to raise the sensitivity in the Z-direction and detect a small acceleration in the dynamic quantity sensor that detects the accelerations in the three axes, there is a need to increase the difference in mass of the weight portions 23 and 24. In order to increase the sensitivity in the Z-direction when using a uniform material, as shown in FIG. 9, there is a need to increase the length of the weight portion 23 in the X-direction to increase the torque.

However, if the weight portion 23 is lengthened, as shown in FIG. 10, a chip size of the entire dynamic quantity sensor including the Z sensor 2 and the XY sensor 3 increases.

In the dynamic quantity sensor 1 according to the present embodiment, the XY sensor 3 is disposed in a space between the connecting portion 231 and the tip portion 232 of the weight portion 23. This makes it possible to reduce an increase in the chip size caused by increasing the length of the weight portion 23 and to improve a detection sensitivity of the acceleration in the Z-direction.

Further, since an increase in the length of the weight portion 23 causes an area of the upper surface of the weight portion 23 required for maintaining the detection sensitivity to be reduced, an increase in the chip size of the dynamic quantity sensor 1 can be reduced.

In the present embodiment, since the Z sensor 2 and the XY sensor 3 are separated from each other, the acceleration in the Z-direction and the acceleration in the X and Y-directions can be detected, independently. Further, in the XY sensor 3, when the fixing portion 31 is disposed on the outer peripheral portion, a parasitic capacitance is generated by a potential difference between the fixing portion 31 and the weight portion 23. However, in the present embodiment, since the frame body 325 is disposed outside the fixing portion 31 as a central anchor, occurrence of the parasitic capacitance can be prevented. As a result, the sensitivity of the other axes decreases, and the detection accuracy can be improved.

In order to improve the detection accuracy of the acceleration in the Z-direction, it is preferable to widen a movable range of the weight portion 23. However, if the recess portion 435 is deepened in order to widen the movable range of the weight portion 23, the distances between the fixed electrode 437 and each of the weight portions 23 and 24 are increased, to thereby lower a detection accuracy.

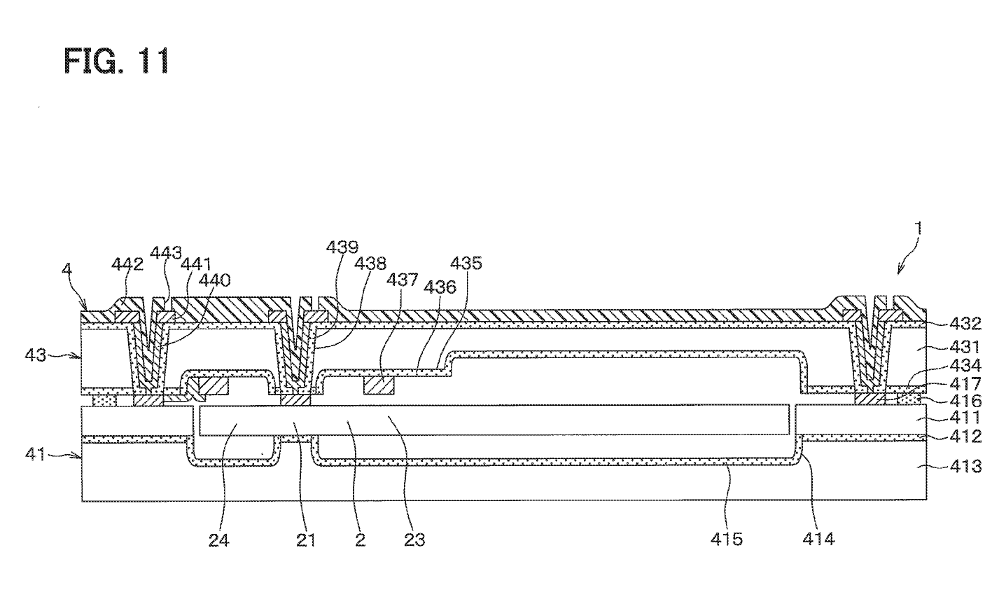

For that reason, as shown in FIG. 11, it is preferable that a recess portion is further provided in a portion of the recess portion 435 which is farther from the fixing portion 21 than the fixed electrode 437, the movable range of the weight portion 23 is widened while maintaining the distances between the fixed electrode 437 and each of the weight portions 23 and 24.

Specifically, when the weight portion 23 is largely displaced, it is preferable that the fixed electrode 437 comes in contact with the weight portion 23 earlier than the recess portion 435 or a recess portion provided inside the recess portion 435, and the movable range of the weight portion 23 is set by the fixed electrode 437.

### Second Embodiment

A second embodiment will be described. In the present embodiment, the configuration of the support portion 4 in the first embodiment is changed. Other configurations are identical with those in the first embodiment, and therefore only parts different from those in the first embodiment will be described.

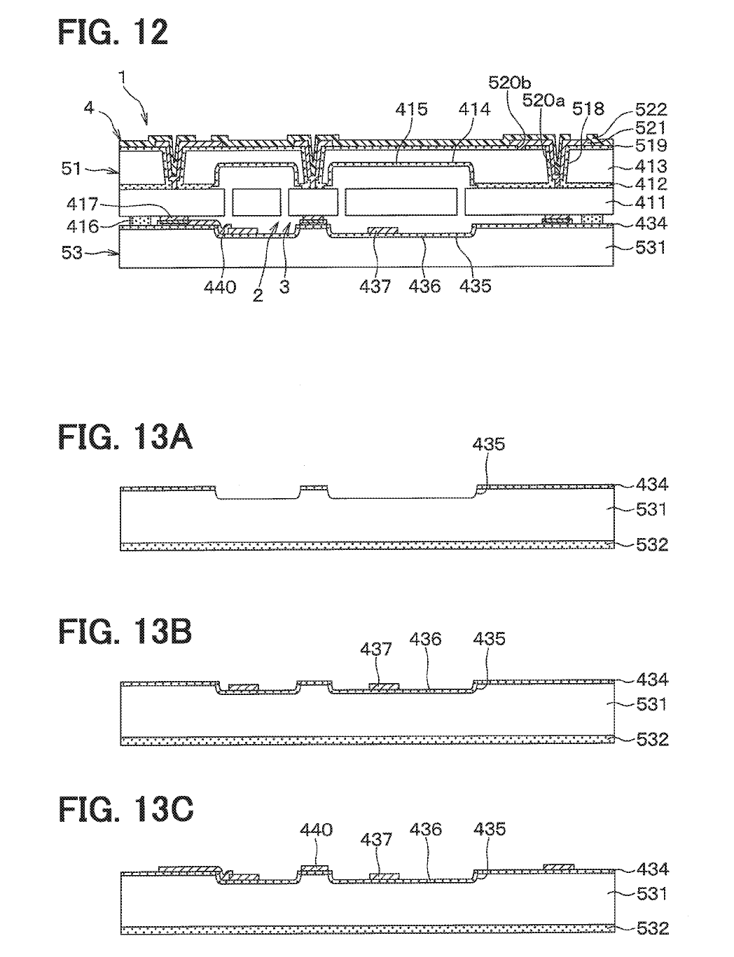

As shown in FIG. 12, in the present embodiment, a support portion 4 includes an MEMS wafer 51 and a CAP wafer 53. The MEMS wafer 51 includes an active layer 411, a sacrificial layer 412, a support layer 413, a spacer 416, and a metal layer 417.

A recess portion 414 is provided in the support layer 413 corresponding to a Z sensor 2 and an XY sensor 3, and an oxide film 415 is formed on a surface of the recess portion 414. Vias 518 are provided in the support layer 413, and an insulating layer 519 is formed on a surface of the vias 518 and a surface of the support layer 413.

In addition, the insulating layer 519 and the sacrificial layer 412 are removed at a bottom portion of each via 518 to provide an opening portion 520a. A wire 521 is formed from an inside of the opening portion 520a to a surface of the insulating layer 519 inside the via 518 and an upper surface of the insulating layer 519. The wire 521 is made of, for example, Al or the like. A portion of the insulating layer 519 formed on a surface of the support layer 413 is partly removed to provide an opening portion 520b. The wire 521 is also formed inside the opening portion 520b, and the active layer 411 and the support layer 413 are electrically connected to each other through the wire 521.

In addition, a passivation film 522 is formed so as to cover the surfaces of the insulating layer 519 and the wire 521. Meanwhile, the passivation film 522 is formed so as to expose a part of the wire 521. In the present embodiment, the fixed electrode 437, the fixing portions 21, 31, and the movable portion 32 are connected to a control device not shown through the wire 521.

The CAP wafer 53 includes a Si layer 531 and an insulating layer 434. Parts of the insulating layer 434 and the Si layer 531 are removed corresponding to the Z sensor 2 and the XY sensor 3 to form a recess portion 435. As with the CAP wafer 43 according to the first embodiment, an oxide film 436 is formed on a surface of the recess portion 435, and the fixed electrode 437 is formed on the surface of the oxide film 436. Similarly to the first embodiment, a wire 440 is formed on the surfaces of the insulating layer 434, the oxide film 436, and the fixed electrode 437. Incidentally, a contact window for taking out a potential from the wire 440 may be provided in the insulating layer 434.

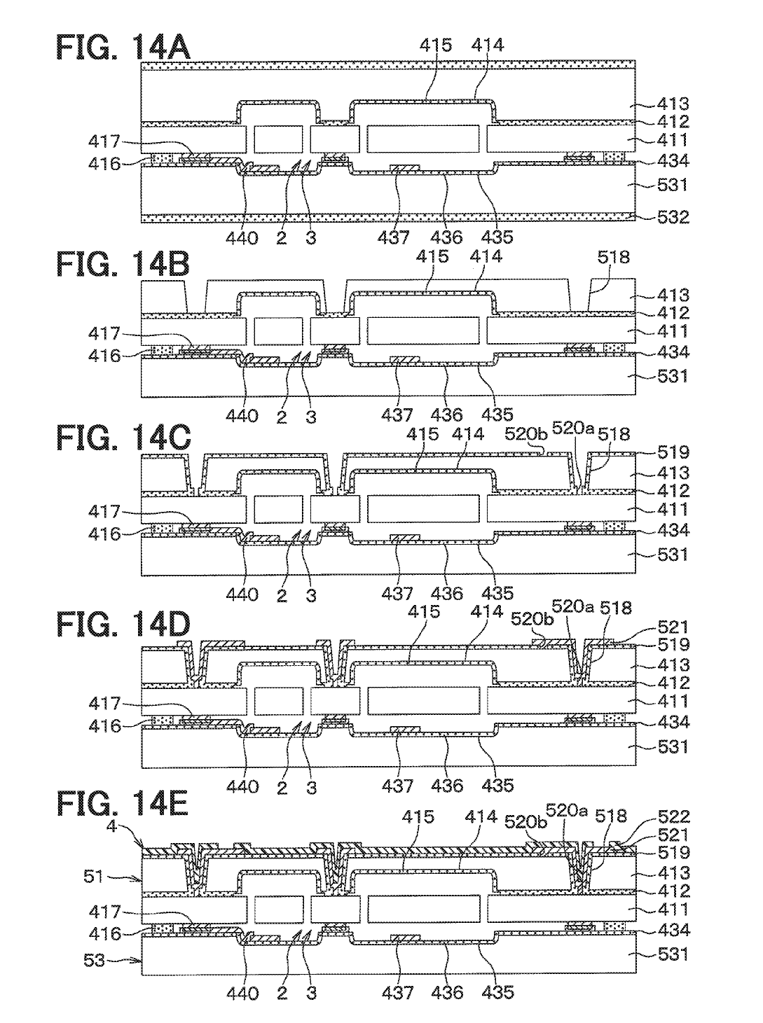

A method of manufacturing the dynamic quantity sensor 1 according to the present embodiment will be described with reference to FIGS. 13A to 13C and FIGS. 14A to 14E. In the present embodiment, the MEMS wafer 51 is manufactured in the same manner as that of the MEMS wafer 41 in the first embodiment, the CAP wafer 53 is manufactured in steps shown in FIGS. 13A to 13C, and the bonding of the MEMS wafer 51 with the CAP wafer 53, and the like, are performed in steps shown in FIGS. 14A to 14 E.

First, a substrate including the Si layer 531 and the insulating layers 434 and 532 formed on a front surface and a back surface of the Si layer 531 is prepared. Then, as shown in FIG. 13A, the insulating layer 434 is removed by etching in portions corresponding to the Z sensor 2 and the XY sensor 3, and a part of the Si layer 531 is removed by etching with the use of the insulating layer 434 as a mask, to thereby form the recess portion 435.

In a step shown in FIG. 13B, the surface of the recess portion 435 is thermally oxidized to form the oxide film 436, and the fixed electrode 437 is formed on the surface of the oxide film 436 by photolithography and etching. In a step shown in FIG. 13C, the wire 440 is formed by photolithography and etching in a portion from the surface of the insulating layer 434 to the surface of the oxide film 436 and the surface of the fixed electrode 437.

In a step shown in FIG. 14A, the MEMS wafer 51 and the CAP wafer 53 are joined together by metal bonding. In a step shown in FIG. 14B, a via 518 that penetrates through the support layer 413 is provided to expose the sacrificial layer 412. The via 518 is provided by removing a portion of the support layer 413 which faces the metal layer 417 by etching.

In a step shown in FIG. 14C, the surface of the support layer 413 on a side opposite to the sacrificial layer 412 and the surface of the via 518 are thermally oxidized or subjected to a CVD method to form the insulating layer 519. Thereafter, the insulating layer 519 and the sacrificial layer 412 located at the bottom portion of the via 518 are removed by etching to form the opening portion 520a and to expose the active layer 411. A part of a portion of the insulating layer 519 which is formed on the surface of the support layer 413 is removed to form the opening portion 520b and to expose the support layer 413. As a result, because all of the layers can be connected to an external wire, and a floating potential is eliminated, parasitic capacitance can be reduced.

In a step shown in FIG. 14D, the wire 521 is formed so as to extend from the surface of the insulating layer 519 to the inside of the opening portion 520a by photolithography and etching to connect the wire 521 and the active layer 411 to each other. The wire 521 is also formed inside the opening portion 520b to connect the active layer 411 and the support layer 413 to each other.

In a step shown in FIG. 14E, the passivation film 522 is formed on the surface of the insulating layer 519 and the surface of the wire 521 by a coating method. Further, an opening portion is provided in the passivation film 522 to expose a part of the wire 521.

Also, in the dynamic quantity sensor 1 of the present embodiment manufactured in this way, the same effects as those in the first embodiment can be obtained.

### Third Embodiment

A third embodiment will be described. In the present embodiment, the configuration of the support portion 4 in the first embodiment is changed. Other configurations are identical with those in the first embodiment, and therefore only parts different from those in the first embodiment will be described.

As shown in FIG. 15, in the present embodiment, a support portion 4 includes an MEMS wafer 61 and a CAP wafer 63. The MEMS wafer 61 includes an Si layer 611, an insulating layer 612, a wire 613, a sacrificial layer 614, a wire 615, a sacrificial layer 616, a thick film poly-Si layer 617, an adhesive 618, and a wire 619.

The insulating layer 612 is formed on an upper surface of the Si layer 611, and the wire 613 is formed on an upper surface of the insulating layer 612. The sacrificial layer 614 is formed on upper surfaces of the insulating layer 612 and the wire 613, and the wire 615 is formed on an upper surface of the sacrificial layer 614. An opening portion is provided in a portion of the sacrificial layer 614 which is located above the wire 613, and the wire 615 is formed so as to reach an inside of the opening portion of the sacrificial layer 614, and is connected to the wire 613. The wire 613 and the wire 615 are made of poly-Si.

The sacrificial layer 616 is formed on upper surfaces of the sacrificial layer 614 and the wire 615, and the thick film poly-Si layer 617 is formed on the upper surfaces of the wire 615 and the sacrificial layer 616. In the present embodiment, the thick film poly-Si layer 617 is processed to form a Z sensor 2 and an XY sensor 3.

In the portions corresponding to the Z sensor 2 and the XY sensor 3, the sacrificial layers 614 and 616 are removed to expose the insulating layer 612, the wire 613, and the wire 615. In the present embodiment, the wire 613 is used as a fixed electrode, and the fixing portions 21, 31, 321 and the wire 613 are connected to a control device not shown through the wire 615.

The adhesive 618 is formed on an upper surface of the thick film poly-Si layer 617, and the MEMS wafer 61 and the CAP wafer 63 are bonded to each other by the adhesive 618 and an adhesive 633 to be described later. In the present embodiment, the adhesive 618 is made of an Al-Ge alloy. Incidentally, the adhesive 618 may be made of glass paste and the MEMS wafer 61 and the CAP wafer 63 may be bonded to each other by glass frit bonding. The wire 619 used as an electrode pad is formed on the upper surface of the thick film poly-Si layer 617.

The CAP wafer 63 includes a substrate 631 and an adhesive 633. In the present embodiment, the substrate 631 is made of glass, but the substrate 631 may be made of Si. A recess portion 632 is formed in the substrate 631 corresponding to the Z sensor 2 and the XY sensor 3, and an adhesive 633 is formed on the surface of the substrate 631 so as to surround the recess portion 632. In the present embodiment, the fixing portions 21, 31, and 321 are not fixed to the CAP wafer 63 but are fixed to the sacrificial layer 616 of the MEMS wafer 61.

In the present embodiment, the adhesive 633 is made of an Al—Ge alloy. The adhesive 633 may be made of eutectic of Au—Ge type or Cu—Sn type, solder, or the like. Further, the adhesive 633 may be made of glass paste, and the MEMS wafer 61 and the CAP wafer 63 may be joined to each other by glass frit bonding.

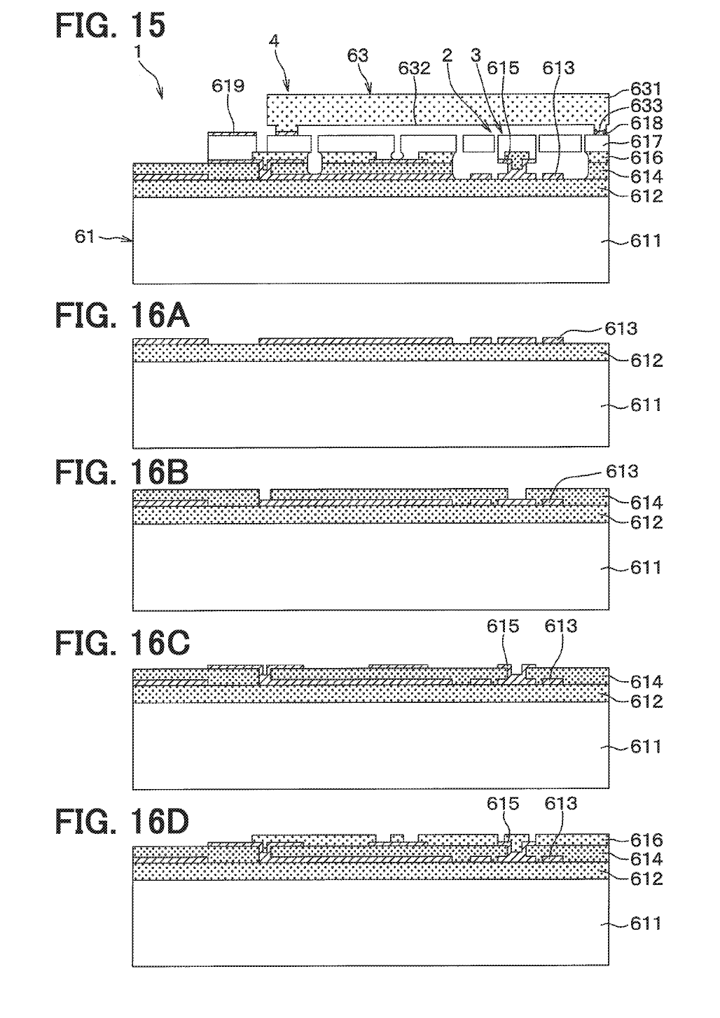

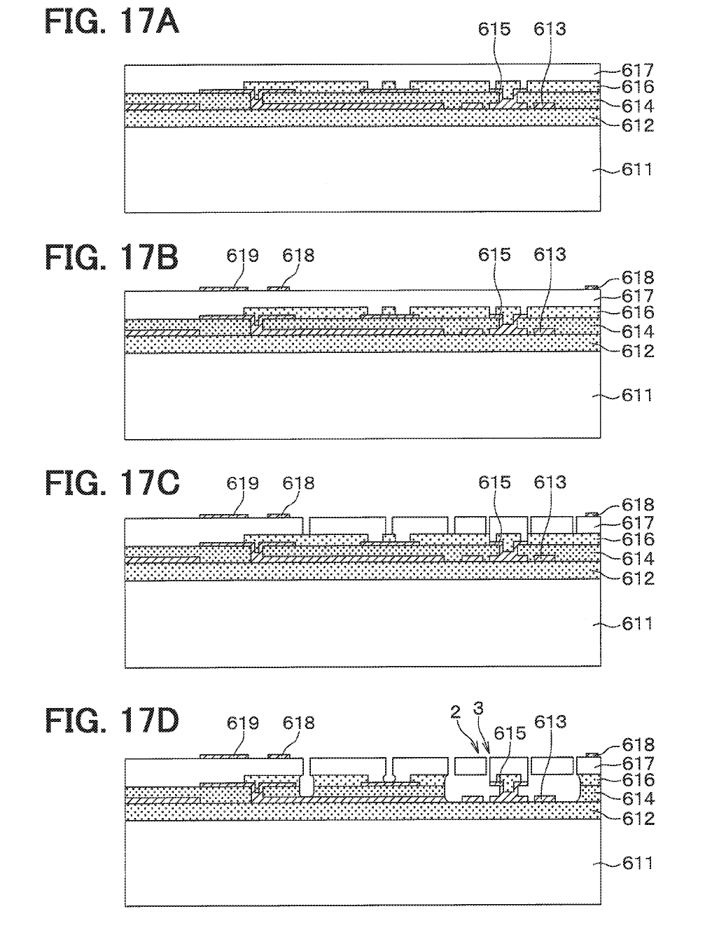

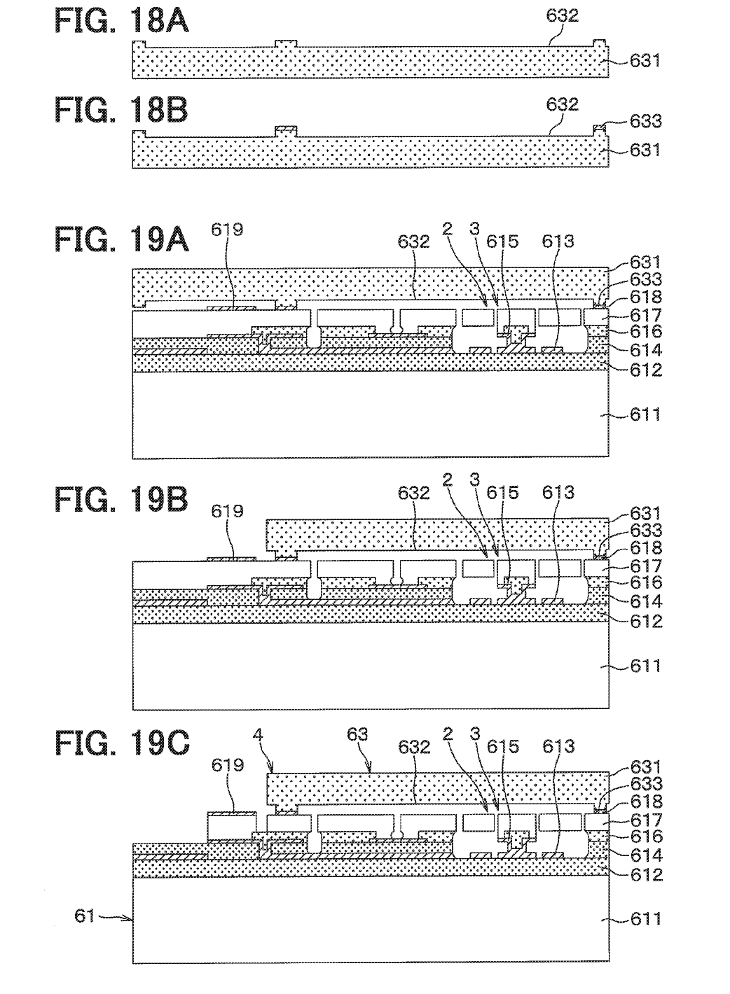

A method of manufacturing the dynamic quantity sensor 1 according to the present embodiment will be described with reference to FIGS. 16A to 19C. The dynamic quantity sensor 1 according to the present embodiment is manufactured in such manner that the MEMS wafer 61 is manufactured in steps shown in FIGS. 16A to 16D and FIGS. 17A to 17D, the CAP wafer 63 is manufactured in steps shown in FIGS. 18A and 18B, and thereafter the MEMS wafer 61 and the CAP wafer 63 are bonded together in steps shown in FIGS. 19A to 19C, and so on.

In a step shown in FIG. 16A, the insulating layer 612 is formed by thermally oxidizing the upper surface of the Si layer 611, and the wire 613 is formed on the upper surface of the insulating layer 612 by photolithography and etching. In a step shown in FIG. 16B, the sacrificial layer 614 is formed on the surface of the wire 613 by the CVD method. At this time, the sacrificial layer 614 is formed so as to expose a part of the wire 613.

In a step shown in FIG. 16C, the wire 615 is formed on the surface of the sacrificial layer 614 and the surface of the wire 613 by photolithography and etching to connect the wire 613 and the wire 615 to each other. In a step shown in FIG. 16D, the sacrificial layer 616 is formed on the surface of the wire 615 by the CVD method. At this time, the sacrificial layer 616 is formed so as to expose a part of the wire 615.

In a step shown in FIG. 17A, the thick film poly-Si layer 617 is formed on the surfaces of the sacrificial layer 614, the wire 615, and the sacrificial layer 616 by the CVD method. In a step shown in FIG. 17B, the adhesive 618 for bonding the MEMS wafer 61 and the CAP wafer 63 together in a step shown in FIG. 19A is patterned by photolithography and etching. In a step shown in FIG. 17B, the wire 619 is formed on the surface of the thick film poly-Si layer 617.

In a step shown in FIG. 17C, the thick film poly-Si layer 617 is processed by etching. In a step shown in FIG. 17D, the sacrificial layers 614 and 616 are selectively removed by the aid of an HF gas, and a part of the thick film poly-Si layer 617 is released from the insulating layer 612 and the wire 613. As a result, the Z sensor 2 and the XY sensor 3 are formed.

In a step shown in FIG. 18A, in a portion corresponding to the Z sensor 2 and the XY sensor 3, a part of the substrate 631 is removed by etching to form the recess portion 632. In a step shown in FIG. 18B, the adhesive 633 is formed on the surface of the substrate 631 so as to surround the recess portion 632.

In a step shown in FIG. 19A, the MEMS wafer 61 and the CAP wafer 63 are joined to each other by Al—Ge eutectic bonding. As a result, the Z sensor 2 and the XY sensor 3 are sealed with the MEMS wafer 61 and the CAP wafer 63.

In a step shown in FIG. 19B, the wire 619 is exposed by half dicing for cutting the substrate 631 while leaving the MEMS wafer 61. In a step shown in FIG. 19C, the thick film poly-Si layer 617 is removed with the use of the wire 619 as a mask to form a device. As a result, the wire 615 is exposed, and the fixing portions 21, 31, and 321 and the wire 613 can be connected to a control device not shown.

Also, in the dynamic quantity sensor 1 of the present embodiment manufactured in this way, the same effects as those in the first embodiment can be obtained.

### Fourth Embodiment

A fourth embodiment will be described. In the present embodiment, the number of Z sensors 2 is changed in the first embodiment. Other configurations are identical with those in the first embodiment, and therefore only parts different from those in the first embodiment will be described.

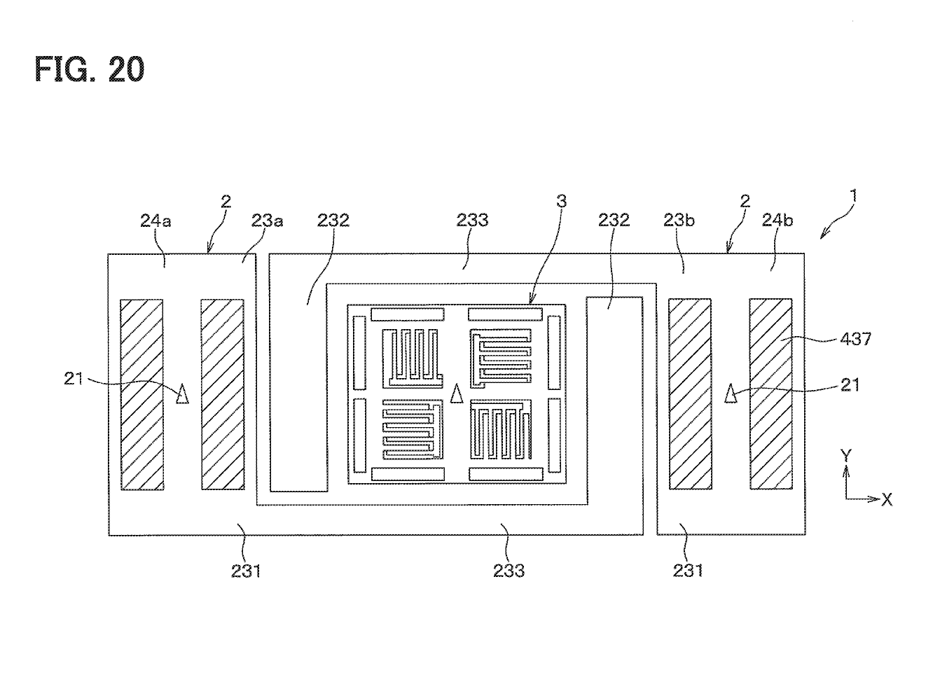

As shown in FIG. 20, a dynamic quantity sensor 1 according to the present embodiment includes two Z sensors 2. In FIG. 20, a beam portion 22 is omitted from illustration.

In the present embodiment, a coupling portion 233 of a weight portion 23 is configured by a single linear beam, and a connecting portion 231 and a tip portion 232 are disposed such that respective end portions of the connecting portion 231 and the tip portion 232 on one side in a Y-direction are connected to each other by a coupling portion 233. The two Z sensors 2 are disposed so that the respective tip portions 232 face each other and the respective coupling portions 233 face each other.

The weight portions 23 and 24 of one of the two Z sensors 2 are defined as weight portions 23a and 24a, respectively, and the weight portions 23 and 24 of the other sensor 2 are defined as weight portions 23b and 24b, respectively. An XY sensor 3 according to the present embodiment is disposed in a space surrounded by the tip portion 232 and the coupling portion 233 of the weight portion 23a, and the tip portion 232 and the coupling portion 233 of the weight portion 23b. In the present embodiment, the two Z sensors 2 are disposed point symmetrically with respect to a center of the XY sensor 3 on an XY-plane.

In the present embodiment, as shown in FIG. 20, four fixed electrodes 437 are formed, two of the four fixed electrodes 437 are disposed on an upper portion of one Z sensor 2, and the remaining two fixed electrodes 437 is disposed on an upper portion of the other Z sensor 2.

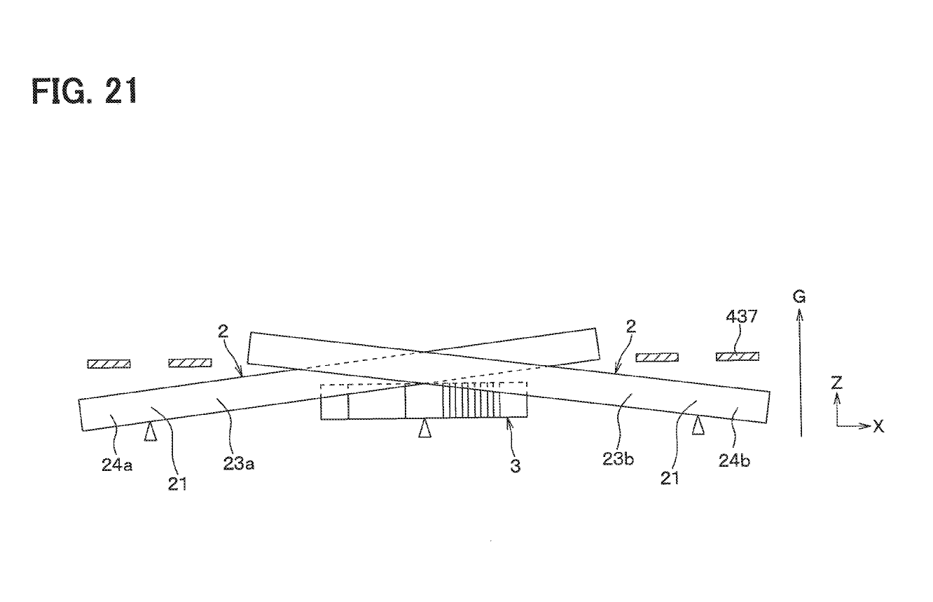

In the present embodiment, when the dynamic quantity sensor 1 is accelerated in a Z-direction, as shown in FIG. 21, each of the two Z sensors 2 operates in the same manner as that of the Z sensor 2 in the first embodiment, and detects the acceleration in the Z-direction with the use of a change in capacitance between the fixed electrodes 437 and the respective weight portions 23 and 24.

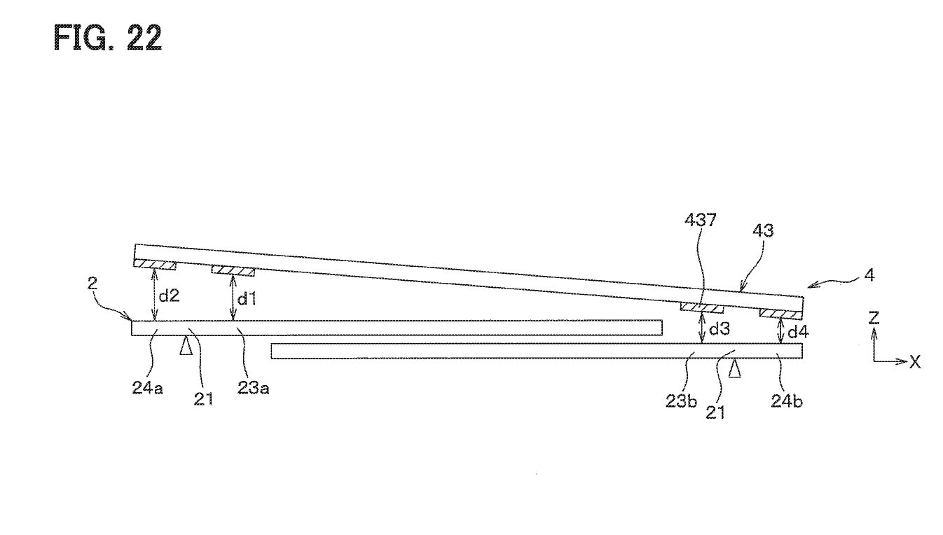

In the case where a support portion 4 is tilted as shown in FIG. 22 due to mounting or the like, a detection accuracy of the acceleration in the Z-direction decreases. In the present embodiment, however, the two Z sensors 2 are disposed in the XY-plane point symmetrically with respect to the center of the XY sensor 3. For that reason, in the case where the support portion 4 is tilted about an axis passing through the center of the XY sensor 3 and being parallel to the Y-direction, the deterioration of detection accuracy can be reduced with the use of the potentials of the four fixed electrodes 437.

As an example, distances between the weight portions 23a, 24a, 23b, and 24b and the fixed electrode 437 that face the respective weight portions when the dynamic quantity sensor 1 is stationary are defined as d1, d2, d3, and d4, and the distances of the respective weight portions and the fixed electrodes 437 when the support portion 4 is not tilted are defined as d0. In that case, d1+d3=2d0 and d2+d4=2d0 are satisfied.

Therefore, when the dynamic quantity sensor 1 is accelerated in the Z-direction, if displacements of the weight portions 23a and 23b by the acceleration in the Z-direction are defined as ·d and displacement of the weight portions 24a and 24b are defined as −·d, then d1+d3=2d0−2·d and d2+d4=2d0+2·d are satisfied.

Potential differences between the fixed electrodes 437 and the weight portions 23, 24 are proportional to the distances between the fixed electrodes 437 and the weight portions 23, 24. For that reason, an average of the potential differences between the fixed electrodes 437 and the weight portions 23a, 23b is obtained, thereby being capable of obtaining d0−·d which is the distance between the weight portions 23 and the fixed electrodes 437 when the support portion 4 is not tilted. Similarly, an average of the potential differences between the fixed electrodes 437 and the weight portions 24a, 24b is obtained, thereby being capable of obtaining d0+·d which is the distance between the weight portions 24 and the fixed electrodes 437 when the support portion 4 is not tilted. Therefore, the acceleration in the Z-direction can be detected when the support portion 4 is not tilted, according to the respective potential differences.

As described above, in the present embodiment, when the support portion 4 is tilted by mounting or the like, the deterioration in detection accuracy can be reduced with the use of the detection results of the two Z sensors 2.

### Fifth Embodiment

A fifth embodiment will be described. In the present embodiment, the configuration of the weight portion 23 and the movable portion 32 is changed in the first embodiment. Other configurations are identical with those in the first embodiment, and therefore only parts different from those in the first embodiment will be described.

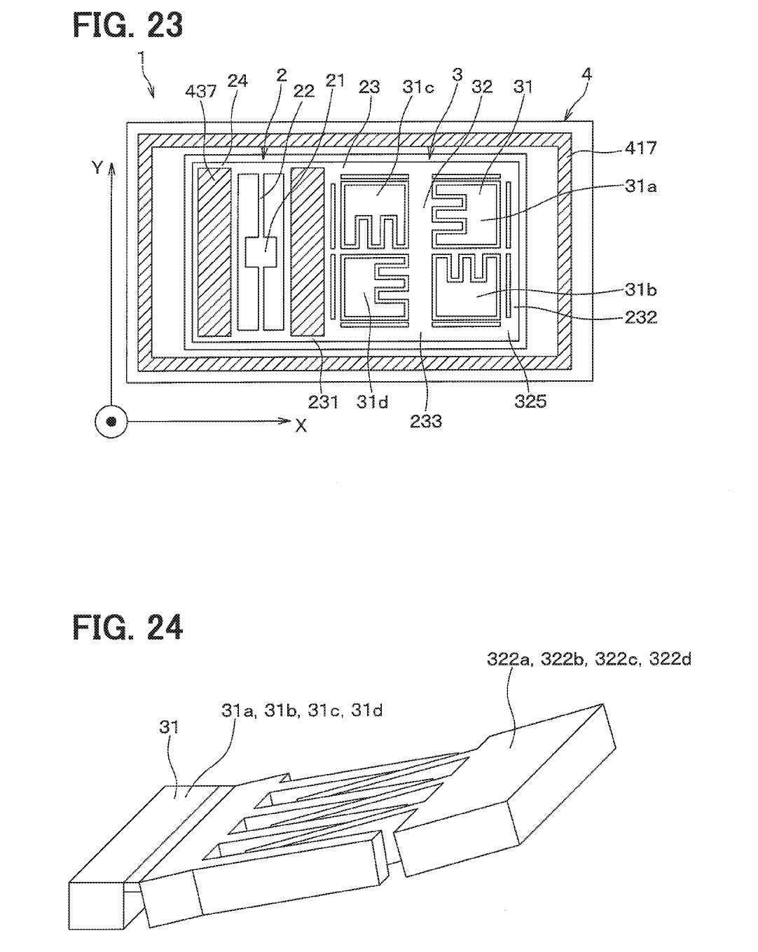

As shown in FIG. 23, in the present embodiment, a weight portion 23 of a Z sensor 2 and a movable portion 32 of an XY sensor 3 are integrated together. A fixing portion 31, which is a part of the XY sensor 3, is disposed in a space between a connecting portion 231 and a tip portion 232.

Specifically, four spaces surrounded by the movable portion 32 are provided between the connecting portion 231 and the tip portion 232, and electrodes 31a, 31b, 31c, and 31d of the fixing portion 31 are disposed in the respective four spaces. In addition, the movable portion 32 has no fixing portion 321, and a sacrificial layer 412 is removed on a back surface of the movable portion 32.

In the present embodiment, the weight portion 23 and the movable portion 32 are integrated together, to thereby fix a potential of the movable portion 32 to 2.5 V, for example, and a potential of a fixed electrode 437 and a potential of each electrode of the fixing portion 31 are used to detect the accelerations in the X, Y, and Z-directions.

In the present embodiment, the weight portion 23 of the Z sensor 2 and the movable portion 32 of the XY sensor 3 are brought into one mass, thereby being capable of further reducing a size of the dynamic quantity sensor 1.

### Sixth Embodiment

A sixth embodiment will be described. In the present embodiment, the configuration of the fixing portion 31 is changed in the fifth embodiment. Other configurations are identical with those in the first embodiment, and therefore only parts different from those in the first embodiment will be described.

As shown in FIG. 24, in the present embodiment, a thickness of a fixing portion 31 is partially reduced to form a spring structure. Specifically, comb teeth-shaped electrodes 31a, 31b, 31c, and 31d are respectively fixed to a sacrificial layer 412 and a CAP wafer 43 at an end portion opposite to a portion where comb teeth are formed. A portion having a thickness in the Z-direction smaller than the thicknesses of the end portion fixed to the sacrificial layer 412 and the end portion formed with the comb teeth is formed between the end portion fixed to the sacrificial layer 412 and the end portion formed with the comb teeth.

In the fifth embodiment, when the weight portion 23 is displaced by acceleration in the Z-direction, a facing area between the respective electrodes of the fixing portion 31 and the respective electrodes of the movable portion 32 changes. However, a displacement of the weight portion 23 is actually sufficiently small, and an influence of the acceleration in the Z-direction on the detection accuracy of the XY sensor 3 is small. However, in order to improve the detection accuracy of the XY sensor 3, it is preferable that the change in the facing area is small.

In the present embodiment, the spring structure is formed on the respective electrodes of the fixing portion 31, as a result of which portions of the respective electrodes where the comb teeth are formed are easily displaced in the Z-direction. For that reason, when the dynamic quantity sensor 1 is accelerated in the Z-direction, as shown in FIG. 24, the portion of the fixing portion 31 where the comb teeth of each electrode are formed is displaced in the same direction as that of the movable portion 32. Therefore, the change in the facing area between the respective electrodes of the fixing portion 31 and the respective electrodes of the movable portion 32 due to the acceleration in the Z-direction is reduced, thereby being capable of improving the detection accuracy of the acceleration in the X-direction and the Y-direction.

### Seventh Embodiment

A seventh embodiment will be described. In the present embodiment, the configuration of the weight portion 23 is changed in the first embodiment. Other configurations are identical with those in the first embodiment, and therefore only parts different from those in the first embodiment will be described.

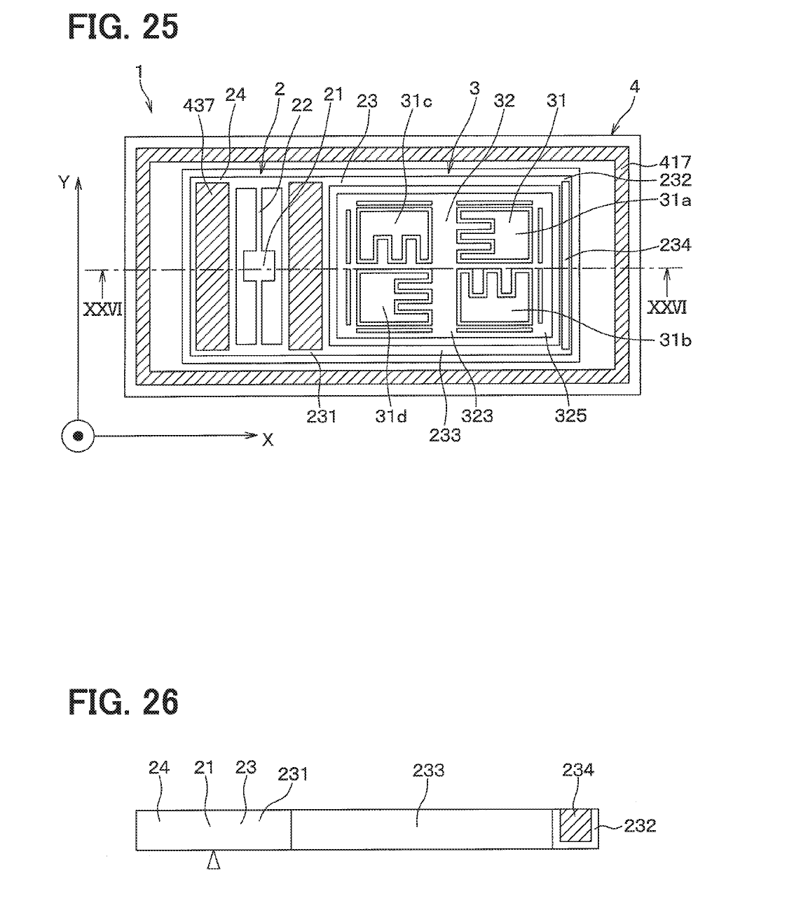

As shown in FIGS. 25 and 26, in the present embodiment, a buried layer 234 for increasing a mass of a weight portion 23 is formed at a tip portion 232 of the weight portion 23. The buried layer 234 is made of, for example, a tungsten plug (W-Plug) or the like.

A drive torque of the weight portion 23 is increased by forming the buried layer 234 in this way, thereby being capable of increasing a difference in torque between the weight portion 23 and the weight portion 24 to improve the detection accuracy of the acceleration in the Z-direction.

### Other Embodiments

It should be noted that the present disclosure is not limited to the embodiments described above, and can be appropriately modified. In addition, each of the above-described embodiments is related to each other, and can be appropriately combined with each other except for a case where the combination is apparently impossible. In the above-described respective embodiments, elements configuring the embodiments are not necessarily indispensable as a matter of course, except when the elements are particularly specified as indispensable and the elements are considered as obviously indispensable in principle. In the above-described respective embodiments, when numerical values such as the number, figures, quantity, a range of configuration elements in the embodiments are described, the numerical values are not limited to a specific number, except when the elements are particularly specified as indispensable and the numerical values are obviously limited to the specific number in principle. In the above-described respective embodiments, when a shape, a positional relationship, and the like of a configuration element and the like are mentioned, the shape, the positional relationship, and the like are not limited thereto excluding a particularly stated case and a case of being limited to specific shape, positional relationship, and the like based on the principle.

For example, the XY sensor 3 may be replaced with a sensor that detects acceleration in any one of an X-direction and a Y-direction. In addition, multiple XY sensors 3 may be disposed in a space between a connecting portion 231 and a tip portion 232. In addition, the XY sensor 3 may include only one of electrodes 31a and 31d and one of electrodes 31b and 31c, and correspondingly, may include only one of electrodes 322a and 322d and one of electrodes 322b and 322c.

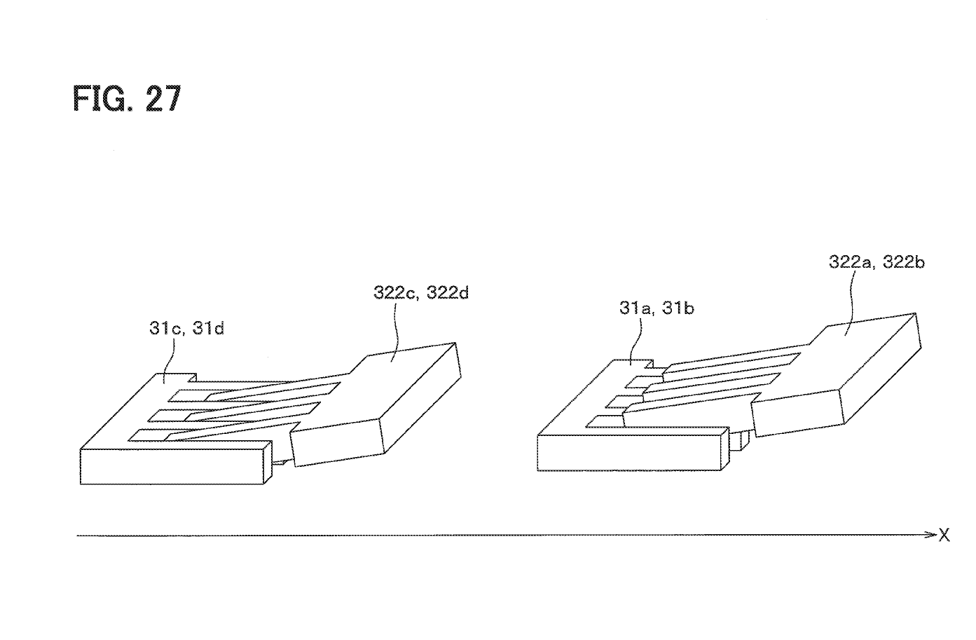

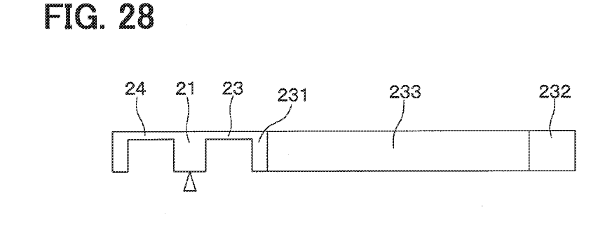

Further, in the fifth embodiment, as shown in FIG. 27, a change in the facing area between the respective electrodes of the fixing portion 31 and the respective electrodes of the movable portion 32 due to the displacement of the weight portion 23 increases more away from the fixing portion 21 in the X-direction. Therefore, the detection result of the acceleration in the X and Y-directions may be corrected with the use of a difference in capacitance between the respective electrodes.

Further, the displacement of the weight portion 23 may be obtained with the use of the two capacitances in the Z sensor 2, and the obtained displacement may be fed back to improve the detection accuracy of the acceleration in the XY sensor 3.

Further, as shown in FIG. 28, the thicknesses of the connecting portion 231 and the weight portion 24 may be reduced, to thereby increase a difference in torque between the weight portion 23 and the weight portion 24. Further, the connecting portion 231 and the weight portion 24 may be processed into a mesh shape, to thereby increase the difference in the torque between the weight portion 23 and the weight portion 24.

Further, according to the first to sixth embodiments, the weight portion 23 is made of the same material as that of the weight portion 24, but the weight portion 23 may be made of a material larger in mass per unit volume than the material of the weight portion 24. Further, in the seventh embodiment, a portion of the weight portion 23 where the buried layer 234 is not formed may be made of a material larger in mass per unit volume than the material of the weight portion 24.

In addition, the dynamic quantity sensor 1 may not include the XY sensor 3, and a device other than the XY sensor 3 may be disposed in the space between the connecting portion 231 and the tip portion 232. Further, the device may not be disposed in the space between the connecting portion 231 and the tip portion 232. Further, the present disclosure may be applied to a dynamic quantity sensor other than the acceleration sensor, for example, a tilt sensor.

1. A dynamic quantity sensor comprising:
a support portion on which a fixed electrode is arranged;
a plate-shaped fixing portion that is fixed to the support portion;
a beam portion that is supported by the fixing portion and extends in one direction on a plane of the fixing portion;
a first weight that is disposed on one side of the fixing portion in an other direction perpendicular to the one direction on the plane of the fixing portion, is coupled to the beam portion, and provides a space between a connecting portion and a tip portion by coupling the connecting portion connecting to the beam portion and the tip portion disposed on a side opposite to the beam portion through a coupling portion extending in the other direction; and
a second weight portion -that is disposed on a side of the fixing portion opposite to the first weight portion in the other direction, and is coupled to the beam portion, wherein:
the first weight portion has a length in the other direction larger than that of the second weight portion; and
a dynamic quantity is detected based on a change in a capacitance between the fixed electrode and each of the first weight portion and the second weight portion when the first weight portion and the second weight portion are displaced.

2. The dynamic quantity sensor according to claim 1, wherein:
the first weight portion is made of a same material as a material of the second weight portion.

3. The dynamic quantity sensor according to claim 1, wherein:
the first weight portion is made of a material having a mass per unit volume larger than a mass per unit of a material of the second weight portion.

4. The dynamic quantity sensor according to claim 1, wherein:
the first weight portion has a mass larger than a mass of the second weight portion.

5. The dynamic quantity sensor according to claim 1, further comprising:
a device (3) at least one device that is partially disposed in the space.

6. The dynamic quantity sensor according to claim 5, wherein:
the dynamic quantity is an acceleration in a normal direction of a surface of the fixing portion; and
the at least one device is a sensor that detects an acceleration in a direction parallel to the surface of the fixing portion.

7. The dynamic quantity sensor according to claim 6, wherein:
the at least one device includes a first electrode and a second electrode which face each other; and
the at least one device detects the acceleration based on the change in the capacitance between the first electrode and the second electrode when the second electrode is displaced relative to the first electrode.

8. The dynamic quantity sensor according to claim 7, wherein:
the first weight portion is spaced apart from the second electrode.

9. The dynamic quantity sensor according to claim 7, wherein:
the first weight portion and the second electrode are integrated together.

10. The dynamic quantity sensor according to claim 9, wherein:
the first electrode is fixed to the support portion at one end portion of the first electrode;
the first electrode faces the second electrode at an other end portion; and
the first electrode has a thickness in the normal direction of the surface of the fixing portion, the thickness between the one end portion fixed to the support portion and the other end portion facing the second electrode being smaller than each of a thicknesses of the one end portion fixed to the support portion and a thickness the other end portion facing the second electrode.

11. The dynamic quantity sensor according to claim 9, wherein:
the at least one device includes a plurality of devices; and
a detection result of the acceleration is corrected based on the difference in the capacitance between the first electrode and the second electrode in each of the plurality of devices.

12. The dynamic quantity sensor according to claim 1, wherein:
the tip portion includes a buried layer for increasing a mass of the first weight portion.

13. The dynamic quantity sensor according to claim 1, wherein:
the fixed electrode defines a movable range of the first weight portion.
